(19) United States
(12) Patent Application Publication
(10) Pub. No.: US 2014/0234782 A1
(43) Pub. Date: Aug. 21, 2014

(54) METHOD FOR MANUFACTURING A SEMICONDUCTOR DEVICE

(71) Applicant: KABUSHIKI KAISHA TOSHIBA, Minato-ku (JP)

(72) Inventor: Tomoya OORI, Mie-ken (JP)

(21) Appl. No.: 13/937,513

(22) Filed: Jul. 9, 2013

Related U.S. Application Data
(60) Provisional application No. 61/766,756, filed on Feb. 20, 2013.

(51) Int. Cl. G03F 7/42; G03F 7/20

(52) U.S. Cl. CPC G03F 7/422; G03F 7/20
USPC 430/325

(57) ABSTRACT

A method for manufacturing a semiconductor device according to an embodiment of the invention includes applying a resist on a substrate surface in a resist application apparatus, light-exposing the resist on the substrate surface in a light exposure apparatus, and after the light-exposing the resist, developing the resist in a development apparatus. The resist is a negative resist. The developing the resist includes mounting the substrate on a support stage including a rotating mechanism of the development apparatus, after the mounting the substrate on the support stage, developing the resist, after the mounting the substrate on the support stage, removing the resist on a peripheral edge of the substrate, and after the developing the resist, and after the removing the resist on the peripheral edge of the substrate, dismounting the substrate from the support stage.

### CROSS-REFERENCE TO RELATED APPLICATIONS

This application is based upon and claims the benefit of priority from U.S. Provisional Patent Application 61/766,756, filed on Feb. 20, 2013; the entire contents of which are incorporated herein by reference.

### FIELD

Embodiments of the invention relate to a method for manufacturing a semiconductor device including the steps of applying a resist, light-exposing the resist, and developing the resist.

### BACKGROUND

The process for manufacturing a semiconductor device includes a lithography step. In the lithography step, first, a resist is applied to the entire surface of a semiconductor substrate. Next, using a light exposure apparatus such as a stepper, the resist is light-exposed in accordance with a mask pattern. Next, the resist is developed. Thus, the resist is patterned in accordance with the mask pattern. In the process for manufacturing a semiconductor device, this patterned resist is used as a mask to perform subsequent steps such as ion implantation or etching.

The lithography step includes the steps of applying a resist, light-exposing the resist, and developing the resist. These steps are performed inside separate units. More specifically, the step of applying a resist is performed in a resist application apparatus. The step of light-exposing the resist is performed in a light exposure apparatus. The step of developing the resist is performed in a development apparatus. Transfer of the semiconductor substrate among the resist application apparatus, the light exposure apparatus, and the development apparatus is performed by a transport apparatus linking these apparatuses. Here, the resist formed at the peripheral edge of the semiconductor substrate is peeled during the process for manufacturing a semiconductor device and causes dust. Thus, the resist applied to the semiconductor substrate peripheral edge needs to be removed during the lithography step.

The removal of the resist at the semiconductor substrate peripheral edge can be performed by selectively applying an organic solvent to the resist at the peripheral edge of the semiconductor substrate being rotated. If the removal of the resist at the semiconductor substrate peripheral edge is performed before the step of light-exposing the resist, then in the step of applying a resist, inside the resist application apparatus, after resist application, the resist at the semiconductor substrate peripheral edge can be removed. Thus, the resist application and the resist removal of the semiconductor substrate peripheral edge can be performed in the same unit. This can suppress the increase of time of the manufacturing process. However, if the removal of the resist at the semiconductor substrate peripheral edge is performed after the step of light-exposing the resist, then the removal of the resist at the semiconductor substrate peripheral edge needs to be performed in a unit different from the development apparatus. The reason for this is as follows. In the case where a positive resist is used, the major ingredient of the developer liquid is typically an alkaline aqueous solution. Thus, the waste liquid of the development apparatus is a mixture of the organic solvent used for resist removal and the alkaline aqueous solution of the developer liquid. This results in increasing the time of the process for manufacturing a semiconductor device. In some lithography steps, there are cases where the removal of the resist at the peripheral edge of the semiconductor substrate needs to be performed after the step of light-exposing the resist. There is demand for a method for manufacturing a semiconductor device capable of removing the resist at the peripheral edge of the semiconductor substrate while suppressing the increase of time of the process for manufacturing a semiconductor device even in such cases.

### BRIEF DESCRIPTION OF THE DRAWING

FIG. 1 is a flow chart of a lithography step in the process for manufacturing a semiconductor device according to a first embodiment;

FIG. 2 is a flow chart of the step of developing the resist in the lithography step according to the first embodiment;

FIG. 3A shows a main part schematic sectional view and a main part schematic plan view of the step of applying a resist according to the first embodiment;

FIG. 3B shows a main part schematic sectional view and a main part schematic plan view of the step of light-exposing the resist according to the first embodiment;

FIG. 4A shows a main part schematic sectional view and a main part schematic plan view of the step of developing the resist according to the first embodiment;

FIG. 4B shows a main part schematic sectional view and a main part schematic plan view of the step of removing the resist at the substrate peripheral edge according to the first embodiment;

FIGS. 5A, 5B, and 6A are main part schematic side views in the development apparatus of the step of developing the resist according to the first embodiment;

FIG. 6B is a main part schematic side view in the development apparatus of the step of removing the resist at the substrate peripheral edge according to the first embodiment;

FIG. 7 is a flow chart of the step of developing the resist in a lithography step according to a second embodiment;

FIG. 8A shows a main part schematic sectional view and a main part schematic plan view of the step of removing the resist at the substrate peripheral edge according to the second embodiment;

FIG. 8B shows a main part schematic sectional view and a main part schematic plan view of the step of developing the resist according to the second embodiment;

FIG. 9A shows a main part schematic side view of the step of removing the resist at the substrate peripheral edge according to the second embodiment; and

FIGS. 9B and 9C are main part schematic side views in the development apparatus of the step of developing the resist according to the second embodiment.

### DETAILED DESCRIPTION

A method for manufacturing a semiconductor device according to an embodiment of the invention includes applying a resist on a substrate surface in a resist application apparatus, light-exposing the resist on the substrate surface in a light exposure apparatus, and after the light-exposing the resist, developing the resist in a development apparatus. The resist is a negative resist. The developing the resist includes mounting the substrate on a support stage including a rotating mechanism of the development apparatus, after the mounting the substrate on the support stage, developing the resist, after the mounting the substrate on the support stage, removing the resist on a peripheral edge of the substrate, and after the developing the resist, and after the removing the resist on the peripheral edge of the substrate, dismounting the substrate from the support stage.

Embodiments of the invention will now be described with reference to the drawings. The figures used in describing the embodiments are schematic for ease of description. The shape, dimension, size relation and the like of components in the figures are not necessarily identical to those in practical application, and can be appropriately modified as long as the effects of the invention are achieved.

### First Embodiment

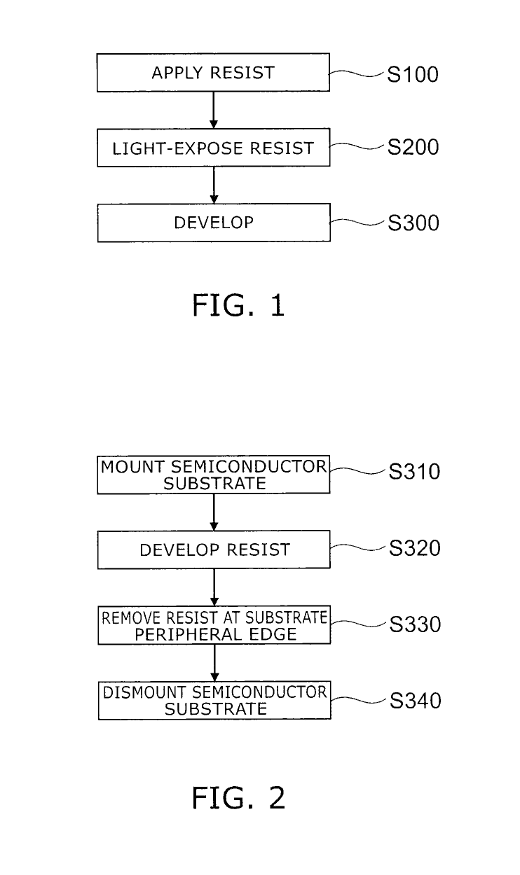

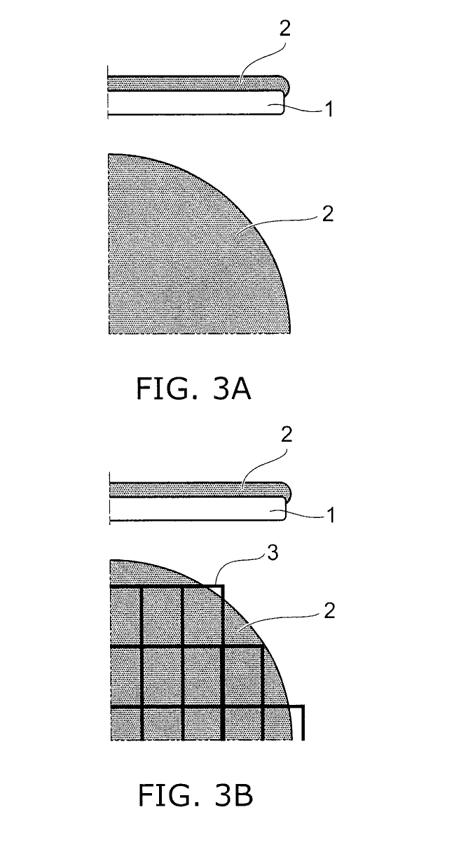

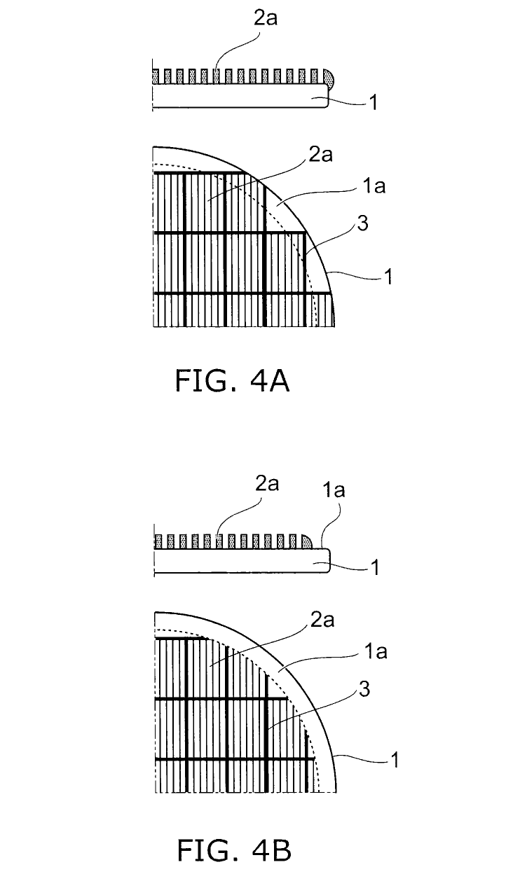

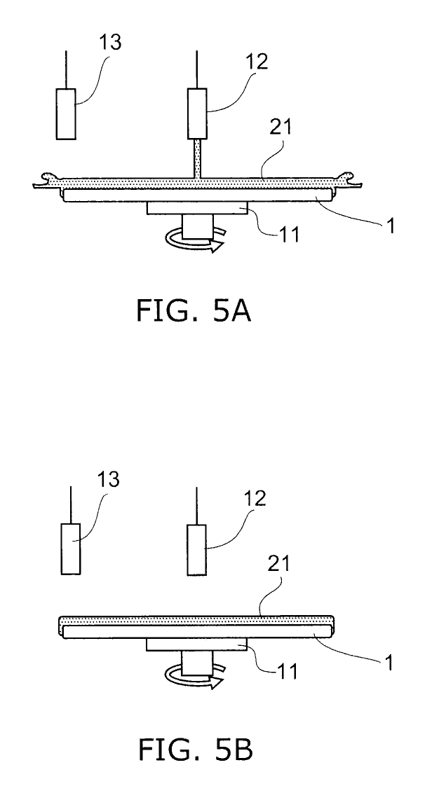

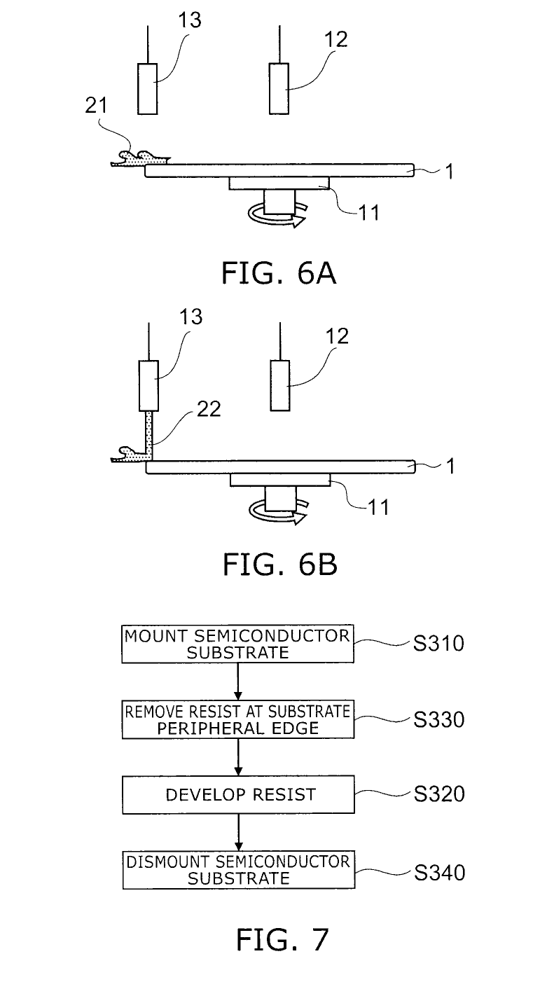

With reference to FIGS. 1 to 6B, a method for manufacturing a semiconductor device according to a first embodiment of the invention is described. FIG. 1 is a flow chart of a lithography step in the process for manufacturing a semiconductor device according to the first embodiment. FIG. 2 is a flow chart of the step of developing the resist in the lithography step according to the first embodiment. FIG. 3A shows a main part schematic sectional view and a main part schematic plan view of the step of applying a resist according to the first embodiment. FIG. 3B shows a main part schematic sectional view and a main part schematic plan view of the step of light-exposing the resist according to the first embodiment. FIG. 4A shows a main part schematic sectional view and a main part schematic plan view of the step of developing the resist according to the first embodiment. FIG. 4B shows a main part schematic sectional view and a main part schematic plan view of the step of removing the resist at the substrate peripheral edge according to the first embodiment. FIGS. 3A, 3B, 4A, and 4B each schematically show a quadrant of the semiconductor substrate. In each of these figures, a schematic sectional view is shown above, and a schematic plan view is shown below. FIGS. 5A, 5B, and 6A are main part schematic side views in the development apparatus of the step of developing the resist according to the first embodiment. FIG. 6B is a main part schematic side view in the development apparatus of the step of removing the resist at the substrate peripheral edge according to the first embodiment.

The method for manufacturing a semiconductor device according to this embodiment includes at least a lithography step shown in FIG. 1. As shown in FIG. 1, the lithography step according to this embodiment includes the step S100 of applying a resist, the step S200 of light-exposing the resist, and the step S300 of developing the resist.

Furthermore, as shown in FIG. 2, the step S300 of developing the resist according to this embodiment includes the step S310 of mounting the semiconductor substrate on a support stage of the development apparatus, the step S320 of developing the resist, the step S330 of removing the resist at the semiconductor substrate peripheral edge, and the step S340 of dismounting the semiconductor substrate from the support stage of the development apparatus.

The detailed description of the step S100 of applying a resist is omitted. This is a step typically performed in the semiconductor manufacturing process, and can be outlined as follows. The step of applying a resist is performed in a resist application apparatus, not shown. The resist processing apparatus is a single unit. The resist application apparatus includes at least a support stage, a resist discharge nozzle, and a resist supply control mechanism. The support stage is provided with a rotating mechanism having a rotation axis in the vertical direction. The resist discharge nozzle is provided so as to be able to discharge a resist from a position generally on the rotation axis of the support stage toward a semiconductor substrate mounted on the support stage. The discharge rate (the amount of discharge per unit time) of the resist discharged from the resist discharge nozzle is controlled by the resist supply control mechanism. By adjusting the number of revolutions of the support stage, the resist discharge rate, and the resist discharge time in the resist application apparatus, the resist is applied onto the semiconductor substrate so as to have a prescribed film thickness. The resist used is a negative resist. In the negative resist, the light-exposed portion is left by development, and the unexposed portion is removed by development. By the step S100 of applying a resist, the negative resist 2 is applied to a prescribed thickness on the semiconductor substrate 1.

Next, the semiconductor substrate 1 applied with the resist 2 is transported to a unit being a light exposure apparatus, not shown, by a transport system, not shown. The resist 2 applied onto the semiconductor substrate 1 is light-exposed in accordance with a mask pattern in the light exposure apparatus, not shown, by the step S200 of light-exposing the resist. The step S200 of light-exposing the resist is a step typically performed in the semiconductor manufacturing process, and the description thereof is omitted. The light exposure apparatus used can be e.g. a conventional stepper, but is not limited thereto. By the step S200 of light-exposing the resist, as shown in FIG. 3B, the resist 2 is light-exposed. The rectangular frame 3 shown on the resist 2 represents a region light-exposed by each shot 3 of the stepper.

Next, the semiconductor substrate 1 having finished the light exposure of the resist 2 is transported to a unit being a development apparatus, not shown, by a transport system, not shown. The step S300 of developing the resist is performed in the development apparatus. The development apparatus is not shown. The side views of the step S320 of developing the resist and the step S330 of removing the resist at the substrate peripheral edge in the development apparatus are shown in FIGS. 5A, 5B, 6A, and 6B.

The development apparatus includes at least a support stage 11, a developer liquid discharge nozzle 12, a resist remover liquid discharge nozzle 13, a developer liquid supply control mechanism, not shown, and a resist remover liquid supply control mechanism, not shown. The support stage 11 is provided with a rotating mechanism having a rotation axis in the vertical direction. The developer liquid discharge nozzle 12 is provided so as to be able to be moved by a movable arm, not shown, from outside the semiconductor substrate mounted on the support stage 11 to a position generally on the rotation axis of the support stage 11. When a developer liquid 21 is discharged onto the semiconductor substrate 1, the developer liquid discharge nozzle 12 discharges the developer liquid 21 from a position generally on the rotation axis of the support stage 11 toward the semiconductor substrate 1 mounted on the support stage 11. The discharge rate and the discharge time of the developer liquid 21 discharged from the developer liquid discharge nozzle 12 are controlled by the developer liquid supply control mechanism.

The resist remover liquid discharge nozzle 13 is provided so as to be able to be moved by a movable arm, not shown, from outside the semiconductor substrate 1 mounted on the support stage 11 to the peripheral edge is of the semiconductor substrate 1. The movable arm of the resist remover liquid discharge nozzle 13 can be moved independently of the movable arm of the developer liquid discharge nozzle 12. When a resist remover liquid 22 is discharged onto the peripheral edge 1a of the semiconductor substrate 1, the resist remover liquid discharge nozzle 13 discharges the resist remover liquid 22 toward a position on the peripheral edge 1a of the semiconductor substrate 1 mounted on the support stage 11. The discharge rate and the discharge time of the resist remover liquid 22 discharged from the resist remover liquid discharge nozzle 13 are controlled by the resist remover liquid supply control mechanism.

In the step S300 of developing the resist, as described above, the step S310 of mounting the semiconductor substrate on the support stage of the development apparatus is first performed in the development apparatus. In this step S310, the semiconductor substrate 1 is mounted on the support stage in the development apparatus. The semiconductor substrate 1 is fixed onto a table of the support stage 11 by e.g. vacuum chuck.

Next, the step S320 of developing the resist is performed. In this step S320, as shown in FIG. 5A, the developer liquid 21 is discharged from the developer liquid discharge nozzle 12 onto the semiconductor substrate 1 mounted on the support stage 11. The developer liquid 21 is an organic solvent used for a negative resist. For instance, the developer liquid 21 is butyl acetate or 2-heptanone. While the developer liquid 21 is discharged from the developer liquid discharge nozzle 12 onto the semiconductor substrate 1, the support stage 11 is rotated. By centrifugal force due to the rotation, the developer liquid 21 is spread toward the outer periphery on the semiconductor substrate 1.

As shown in FIG. 5B, the discharge of the developer liquid 21 from the developer liquid discharge nozzle 12 is stopped. The support stage 11 is rotated at a prescribed number of revolutions per prescribed time to apply the developer liquid 21 onto the semiconductor substrate 1. Thus, the resist 2 on the semiconductor substrate 1 is developed. While the developer liquid 21 covers the surface of the resist 2, the development of the resist 2 proceeds. During the development, the unexposed portion of the resist 2 is dissolved into the developer liquid. Depending on the number of revolutions of the support stage 11, the film thickness of the developer liquid 21 on the semiconductor substrate 1 is determined. Depending on this film thickness, the development time is determined appropriately.

Next, as shown in FIG. 6A, the number of revolutions of the support stage 11 is made higher than the number of revolutions in FIG. 5B. Thus, the developer liquid 21 on the semiconductor substrate 1 is spun off to the outside of the semiconductor substrate 1 by centrifugal force. As a result, the resist 2a having a mask pattern is left on the semiconductor substrate 1. Here, the developer liquid 21 may fail to be sufficiently spun off from above the semiconductor substrate 1, and a residue of the developer liquid 21 may be left. In this case, the top of the semiconductor substrate 1 can be further washed with a rinse liquid. The rinse liquid, like the developer liquid 21, can be discharged from another nozzle, not shown, onto the semiconductor substrate 1. After washing, the rinse liquid is spun off, like the developer liquid 21, by centrifugal force due to the rotation of the semiconductor substrate 1. The rinse liquid used is e.g. MIBC (methyl isobutyl carbinol).

The development apparatus is provided with a generally cylindrical cup, not shown, surrounding the periphery of the support stage 11. The developer liquid 21 spun off from the surface of the semiconductor substrate 1 is received by the sidewall of this cup. The developer liquid 21 is then carried downward on the sidewall and collected in a waste liquid collection container, not shown, provided in the development apparatus.

In the step S320 of developing the resist, the temporal profile of the discharge rate of the developer liquid 21 discharged from the developer liquid discharge nozzle 12 and the temporal profile of the number of revolutions of the support stage 11 are configured appropriately depending on the situation.

By the step S320 of developing the resist, as shown in FIG. 4A, the resist 2a on the semiconductor substrate 1 is developed so as to have a mask pattern. The resist 2a in each shot 3 by the stepper has a mask pattern. The resist 2 outside the shot 3 is removed by development. For ease of description, the mask pattern of the resist 2a in the shot 3 is represented by multiple stripes. In practice, the mask pattern of the resist 2a in the shot 3 has a pattern corresponding to each process.

The circumference represented by the dashed line inside the outer periphery of the semiconductor substrate 1 is depicted to schematically indicate the peripheral edge of the semiconductor substrate. The region interposed between the outer periphery of the semiconductor substrate 1 and the circumference of the dashed line is the peripheral edge of the semiconductor substrate. The width of the peripheral edge can be arbitrarily determined depending on the situation. For instance, the width of the peripheral edge is several mm. Some of the shots 3 by the stepper cover the peripheral edge of the semiconductor substrate. Thus, after the step S320 of developing the resist is performed, the resist 2a having a mask pattern is located on the peripheral edge of the semiconductor substrate 1.

Next, the step S330 of removing the resist at the semiconductor substrate peripheral edge is performed. As shown in FIG. 6B, with the support stage 11 rotated at a prescribed number of revolutions, the resist remover liquid 22 is selectively discharged from the resist remover liquid discharge nozzle 13 onto the peripheral edge 1a of the semiconductor substrate 1. Thus, as shown in FIG. 4B, the portion of the resist 2a having a mask pattern located on the peripheral edge 1a of the semiconductor substrate 1 is selectively removed. The discharge rate and the discharge time of the resist remover liquid 22 and the number of revolutions of the support stage 11 are configured appropriately. The resist remover liquid 22 is an organic solvent, and can be any solvent capable of dissolving the resist. The resist remover liquid 22 includes e.g. at least one of gamma-butyrolactone, cyclohexanone, propylene glycol monomethyl ether acetate (PGMEA), and propylene glycol monomethyl ether (PGME).

After the discharge of the resist remover liquid 22 from the resist remover liquid nozzle 13 is stopped, the resist remover liquid 22 on the peripheral edge 1a of the semiconductor substrate 1 is spun off to the outside of the semiconductor substrate 1 by centrifugal force due to the rotation of the semiconductor substrate, as in the case of the developer liquid 21. The resist remover liquid 22 spun off from the surface of the semiconductor substrate 1 is received by the sidewall of the cup. The resist remover liquid 22 is then carried downward on the sidewall and collected in the waste liquid collection container in which the developer liquid 21 was collected. The resist remover liquid 22 is an organic solvent like the developer liquid 21. Thus, the resist remover liquid 22 can be collected together in the same waste liquid collection container.

Here, in the case where the resist 2 is a positive resist, the developer liquid is an alkaline aqueous solution. Thus, the developer liquid cannot be collected in the same waste liquid collection container as the aforementioned resist remover liquid 22. This is because the waste liquid of the alkaline aqueous solution and the waste liquid of the organic solvent must be separately collected in waste liquid collection. Thus, in the case where the resist 2 is a positive resist, unlike the method for manufacturing a semiconductor device according to this embodiment, the step S330 of removing the resist at the semiconductor substrate peripheral edge cannot be performed in the development apparatus where the step S320 of developing the resist was performed. Accordingly, the step S330 of removing the resist at the semiconductor substrate peripheral edge must be performed after transport to a different unit of the processing apparatus by the transport system. This increases the time of the manufacturing process by the time for transporting the semiconductor substrate to the different unit.

Next, the step S340 of dismounting the semiconductor substrate from the support stage of the development apparatus is performed. By this step, the semiconductor substrate 1 is dismounted to the outside of the development apparatus. On the surface of the semiconductor substrate 1, the resist 2a having a mask pattern has been formed. On the peripheral edge 1a of the semiconductor substrate 1, the resist 2 has been removed along the circumference. Subsequently, in the step such as etching or ion implantation, this resist 2a is used as a mask to process a to-be-processed film between the semiconductor substrate 1 and the resist 2a. Furthermore, well-known manufacturing steps are performed as necessary to provide a semiconductor device.

As described above, in the method for manufacturing a semiconductor device according to this embodiment, a negative resist 2 is applied onto the semiconductor substrate 1 and light-exposed. The semiconductor substrate 1 having finished the light exposure is mounted on the support stage 11 in the development apparatus. Then, before the semiconductor substrate 1 is dismounted from the support stage 11, the step S320 of developing the resist and the step S330 of removing the resist at the semiconductor substrate peripheral edge are performed in the development apparatus. That is, between the step S320 of developing the resist and the step S330 of removing the resist at the semiconductor substrate peripheral edge, there is no need to transport the semiconductor substrate between processing apparatuses (units). This can reduce the time of the process for manufacturing a semiconductor device. Furthermore, in the development apparatus, the waste liquid collection of the developer liquid 21 and the waste liquid collection of the resist remover liquid 22 can be performed using the same waste liquid collection container. This can simplify the structure of the development apparatus used in the method for manufacturing a semiconductor device according to this embodiment.

### Second Embodiment

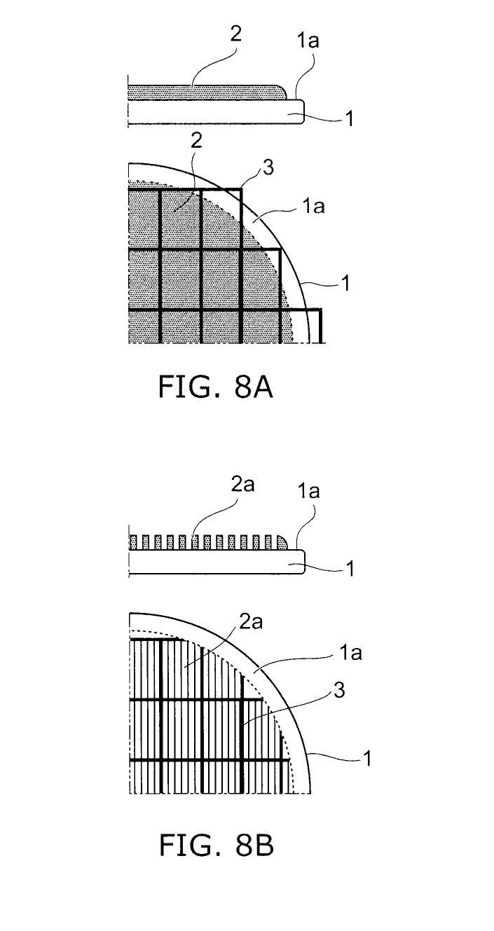

With reference to FIGS. 7 to 9C, a method for manufacturing a semiconductor device according to a second embodiment of the invention is described. FIG. 7 is a flow chart of the step 5300 of developing the resist in a lithography step according to the second embodiment. The flow chart of the lithography step according to this embodiment is the same as the flow chart of the lithography step according to the first embodiment of FIG. 1, and hence is omitted. FIG. 8A shows a main part schematic sectional view and a main part schematic plan view of the step of removing the resist at the substrate peripheral edge according to the second embodiment. FIG. 8B shows a main part schematic sectional view and a main part schematic plan view of the step of developing the resist according to the second embodiment. FIGS. 8A and 8B each schematically show a quadrant of the semiconductor substrate, and correspond to FIGS. 3A to 4B according to the first embodiment. In each of these figures, a schematic sectional view is shown above, and a schematic plan view is shown below. Here, the portions having the same configuration as those described in the first embodiment are labeled with like reference numerals or symbols, and the description thereof is omitted. The differences from the first embodiment are primarily described.

In the method for manufacturing a semiconductor device according to this embodiment, as shown in FIG. 7, after the step S330 of removing the resist at the semiconductor substrate peripheral edge is performed, the step S320 of developing the resist is performed. In this point, the method for manufacturing a semiconductor device according to this embodiment is different from the method for manufacturing a semiconductor device according to the first embodiment.

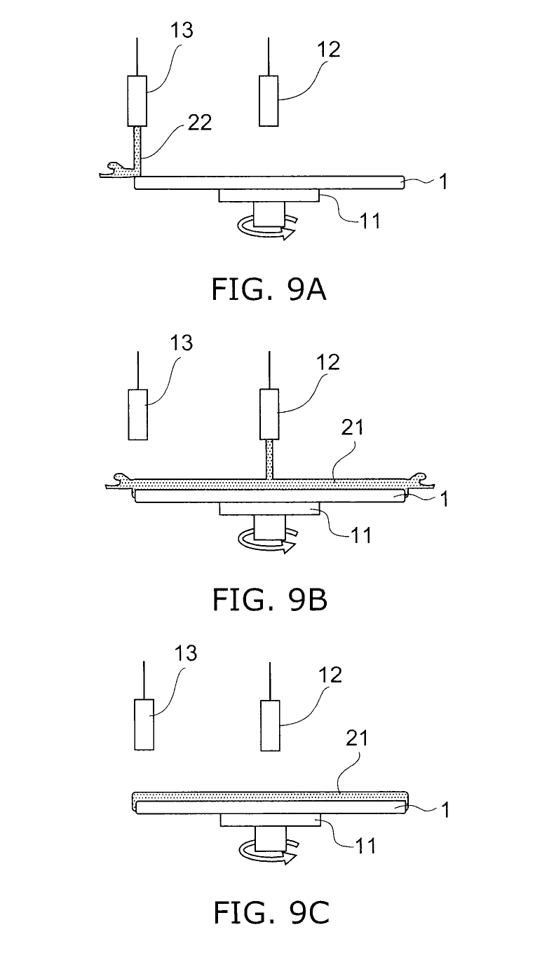

In the following, the above difference is described. After the step S100 of applying a resist and the step S200 of light-exposing the resist are performed, the semiconductor substrate 1 having the light-exposed negative resist 2 on the surface is mounted on the support stage 11 in the development apparatus as in the method for manufacturing a semiconductor device according to the first embodiment. Next, as shown in FIG. 9A, in the development apparatus, with the support stage 11 rotated at a prescribed number of revolutions, the resist remover liquid 22 is discharged from the resist remover liquid discharge nozzle 13 onto the peripheral edge 1a of the semiconductor substrate 1. Thus, the resist remover liquid 22 is selectively discharged onto the resist 2 on the peripheral edge 1a of the semiconductor substrate 1 along the outer periphery of the semiconductor substrate 1. As a result, as shown in FIG. 8A, the resist 2 is selectively removed along the outer periphery of the semiconductor substrate 1 on the peripheral edge 1a of the semiconductor substrate 1. The discharge rate and the discharge time of the resist remover liquid 22 and the number of revolutions of the support stage 11 are configured appropriately. The resist remover liquid 22 is an organic solvent, and can be any solvent capable of dissolving the resist, as in the first embodiment.

Next, the discharge of the resist remover liquid 22 from the resist remover liquid nozzle 13 is stopped. By centrifugal force due to the rotation of the semiconductor substrate, the resist remover liquid 22 is spun off to the outside of the semiconductor substrate 1. The resist remover liquid 22 spun off from the surface of the semiconductor substrate 1 is received, as in the first embodiment, by the sidewall of a generally cylindrical cup, not shown, surrounding the periphery of the support stage 11. The resist remover liquid 22 is then carried downward on the sidewall and collected in a waste liquid collection container provided in the development apparatus.

Next, the step S320 of developing the resist is performed. In this step S320, as shown in FIG. 9B, the developer liquid 21 is discharged from the developer liquid discharge nozzle 12 onto the semiconductor substrate 1 mounted on the support stage 11. As in the first embodiment, the developer liquid 21 is an organic solvent used for a negative resist. While the developer liquid 21 is discharged from the developer liquid discharge nozzle 12 onto the semiconductor substrate 1, the support stage 11 is rotated. By centrifugal force due to the rotation, the developer liquid 21 is spread toward the outer periphery on the semiconductor substrate 1.

As shown in FIG. 9C, as in the first embodiment, the discharge of the developer liquid 21 from the developer liquid discharge nozzle 12 is stopped. The support stage 11 is rotated at a prescribed number of revolutions per prescribed time to apply the developer liquid 21 onto the semiconductor substrate 1. Thus, the resist 2 on the semiconductor substrate 1 is developed. While the developer liquid 21 covers the surface of the resist 2, the development of the resist 2 proceeds. During the development, the unexposed portion of the resist 2 is dissolved into the developer liquid. Depending on the number of revolutions of the support stage, the film thickness of the developer liquid is determined. Depending on this film thickness, the development time is determined appropriately.

Next, as shown in FIG. 6A of the first embodiment, the number of revolutions of the support stage 11 is made higher than the number of revolutions in FIG. 9C. Thus, the developer liquid 21 on the semiconductor substrate 1 is spun off to the outside of the semiconductor substrate 1 by centrifugal force. As a result, the resist 2a having a mask pattern is left on the semiconductor substrate 1. Here, the developer liquid 21 may fail to be sufficiently spun off from above the semiconductor substrate 1, and a residue of the developer liquid 21 may be left. In this case, the top of the semiconductor substrate 1 can be further washed with a rinse liquid. The rinse liquid, like the developer liquid 21, can be discharged from another nozzle, not shown, onto the semiconductor substrate. After washing, the rinse liquid is spun off, like the developer liquid 21, by centrifugal force due to the rotation of the semiconductor substrate 1. The rinse liquid used is e.g. MIBC (methyl isobutyl carbinol).

The developer liquid 21 spun off from the surface of the semiconductor substrate 1 is received by the sidewall of the generally cylindrical cup, not shown, surrounding the periphery of the support stage 11. The developer liquid 21 is then carried downward on the sidewall and collected in the waste liquid collection container in which the resist remover liquid 22 was collected. The developer liquid 21 is an organic solvent like the resist remover liquid 22. Thus, the developer liquid 21 can be collected together in the same waste liquid collection container.

In the step S320 of developing the resist, the temporal profile of the discharge rate of the developer liquid 21 discharged from the developer liquid discharge nozzle 12 and the temporal profile of the number of revolutions of the support stage are configured appropriately depending on the situation.

By the step S320 of developing the resist, as shown in FIG. 8B, the resist 2a on the semiconductor substrate 1 is developed so as to have a mask pattern. The resist 2a in each shot 3 by the stepper has a mask pattern. The resist 2 outside the shot 3 is removed by development.

As described above, also in the method for manufacturing a semiconductor device according to this embodiment, as in the method for manufacturing a semiconductor device according to the first embodiment, a negative resist 2 is applied onto the semiconductor substrate 1 and light-exposed. The semiconductor substrate 1 having finished the light exposure is mounted on the support stage 11 in the development apparatus. Then, before the semiconductor substrate 1 is dismounted from the support stage 11, the step S320 of developing the resist and the step S330 of removing the resist at the semiconductor substrate peripheral edge are performed in the development apparatus. That is, between the step S320 of developing the resist and the step S330 of removing the resist at the semiconductor substrate peripheral edge, there is no need to transport the semiconductor substrate between processing apparatuses (units). This can reduce the time of the process for manufacturing a semiconductor device. Furthermore, in the development apparatus, the waste liquid collection of the developer liquid 21 and the waste liquid collection of the resist remover liquid 22 can be performed using the same waste liquid collection container. This can simplify the structure of the development apparatus used in the method for manufacturing a semiconductor device according to this embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A method for manufacturing a semiconductor device, comprising:
applying a resist on a substrate surface in a resist application apparatus;
light-exposing the resist on the substrate surface in a light exposure apparatus; and
after the light-exposing the resist, developing the resist in a development apparatus,
the resist being a negative resist, and
the developing the resist including:
mounting the substrate on a support stage including a rotating mechanism of the development apparatus;
after the mounting the substrate on the support stage, developing the resist;
after the mounting the substrate on the support stage, removing the resist on a peripheral edge of the substrate; and
after the developing the resist, and after the removing the resist on the peripheral edge of the substrate, dismounting the substrate from the support stage.

2. The method according to claim 1, wherein the removing the resist on the peripheral edge of the substrate is performed after the developing the resist.

3. The method according to claim 2, wherein
in the developing the resist, a developer liquid made of an organic solvent is applied onto a surface of the resist on the substrate, and an unexposed portion of the resist is removed by the developer liquid, and
in the removing the resist on the peripheral edge of the substrate, with the support stage rotated, a resist remover liquid made of an organic solvent is discharged onto the resist on the peripheral edge of the substrate, and the resist on the peripheral edge of the substrate is removed by the resist remover liquid.

4. The method according to claim 3, wherein the developer liquid applied onto the surface of the resist and the resist remover liquid discharged onto the resist on the peripheral edge of the substrate are collected in a same waste liquid collection container provided in the development apparatus.

5. The method according to claim 2, wherein the resist remover liquid is an organic solvent used as a solvent of the resist.

6. The method according to claim 5, wherein the resist remover liquid includes at least one of gamma-butyrolactone, cyclohexanone, propylene glycol monomethyl ether acetate (PGMEA), and propylene glycol monomethyl ether (PGME).

7. The method according to claim 1, wherein the developing the resist is performed after the removing the resist on the peripheral edge of the substrate.

8. The method according to claim 7, wherein
in the developing the resist, a developer liquid made of an organic solvent is applied onto a surface of the resist on the substrate, and an unexposed portion of the resist is removed by the developer liquid, and
in the removing the resist on the peripheral edge of the substrate, with the support stage rotated, a resist remover liquid made of an organic solvent is discharged onto the resist on the peripheral edge of the substrate, and the resist on the peripheral edge of the substrate is removed by the resist remover liquid.

9. The method according to claim 8, wherein the developer liquid applied onto the surface of the resist and the resist remover liquid discharged onto the resist on the peripheral edge of the substrate are collected in a same waste liquid collection container provided in the development apparatus.

10. The method according to claim 7, wherein the resist remover liquid is an organic solvent used as a solvent of the resist.

11. The method according to claim 10, wherein the resist remover liquid includes at least one of gamma-butyrolactone, cyclohexanone, propylene glycol monomethyl ether acetate (PGMEA), and propylene glycol monomethyl ether (PGME).
